(19) United States
(12) Patent Application Publication
(10) Pub. No.: US 2019/0108860 A1
(43) Pub. Date: Apr. 11, 2019

(54) TOOL-LESS MOUNTING APPARATUS FOR HARD DISK DRIVE AND STORAGE DEVICE USING THE SAME

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: HE-TAO HAN, Wuhan (CN); JUN-HUA TAN, Wuhan (CN); XIAO-ZHONG JING, Wuhan (CN); YI-SHENG LIN, New Taipei (TW); LIANG-CHIN WANG, New Taipei (TW)

(21) Appl. No.: 15/891,193

(22) Filed: Feb. 7, 2018

(30) Foreign Application Priority Data
Oct. 11, 2017 (CN) 201710973694.0

(51) Int. Cl. G11B 33/00; G06F 1/18; G11B 33/12; H05K 5/02

(52) U.S. Cl. CPC G11B 33/005; H05K 5/0221; G11B 33/124; G06F 1/187

(57) ABSTRACT

A hand-mountable mounting apparatus for hard disk drives (HDD) and storage devices using HDD includes a tray defining an installation space for the hard disk drive and a locking unit. The tray includes a hook. A bracket of the locking unit includes defines a first locking slot corresponding to the hook and a sliding plate defining a second locking slot corresponding to the hook and the first locking slot. The sliding plate is slidable between an unlock position, where the hook is free to withdraw, and a lock position, where the first locking slot and the second locking slot are not aligned and the hook is latched by the sliding plate.

### FIELD

The subject matter herein generally relates to a tool-less mounting apparatus for hard disk drives and storage devices using a hand-mounting apparatus.

### BACKGROUND

Most hard disks are provided in rectangular parallelepiped cases with screw holes that permit the cases to be mounted in a computer chassis, as fixed internal devices. Installing a hard disk drive can involve opening a computer case, screwing the hard disk drive to the computer chassis, and closing the computer case, which typically involves the use of tools. The burden involved in installing and uninstalling a hard disk drive can be unacceptable for systems that are updated frequently. Therefore, a mounting apparatus for hard disk drives which can be fitted by hand and storage devices using the mounting apparatus would be beneficial.

### BRIEF DESCRIPTION OF THE DRAWINGS

Implementations of the present disclosure will now be described, by way of example only, with reference to the attached figures.

FIG. 1 illustrates an isometric view of an exemplary embodiment of a storage device, showing the mounting apparatus in a locking position.

FIG. 2 illustrates an exploded view of the storage device of FIG. 1.

FIG. 3 illustrates the storage device of FIG. 1, showing the mounting apparatus in an unlocking position.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein can be practiced without these specific details.

In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the exemplary embodiments described herein.

Several definitions that apply throughout this disclosure will now be presented.

The term “comprising” means “including, but not necessarily limited to”; it specifically indicates open-ended inclusion or membership in a so-described combination, group, series, and the like.

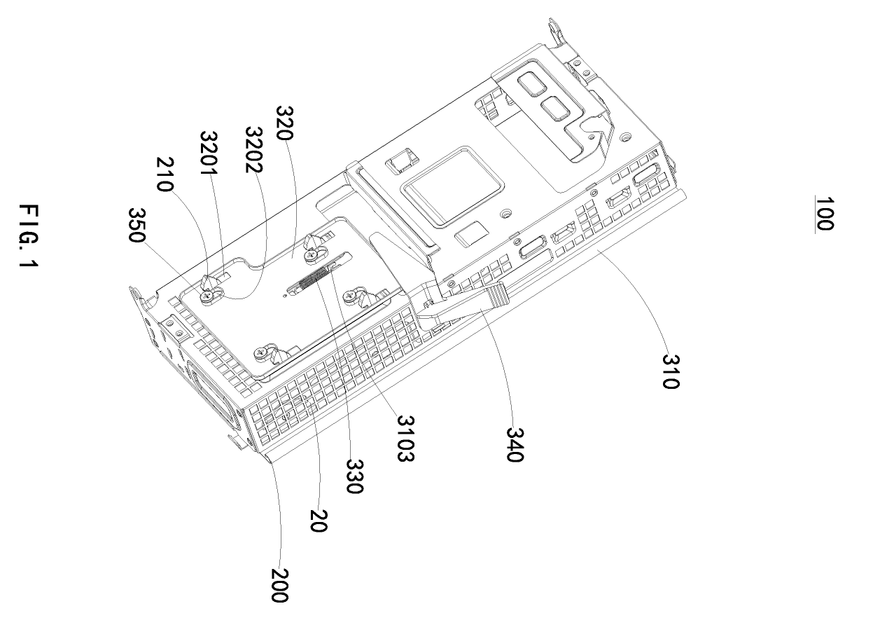

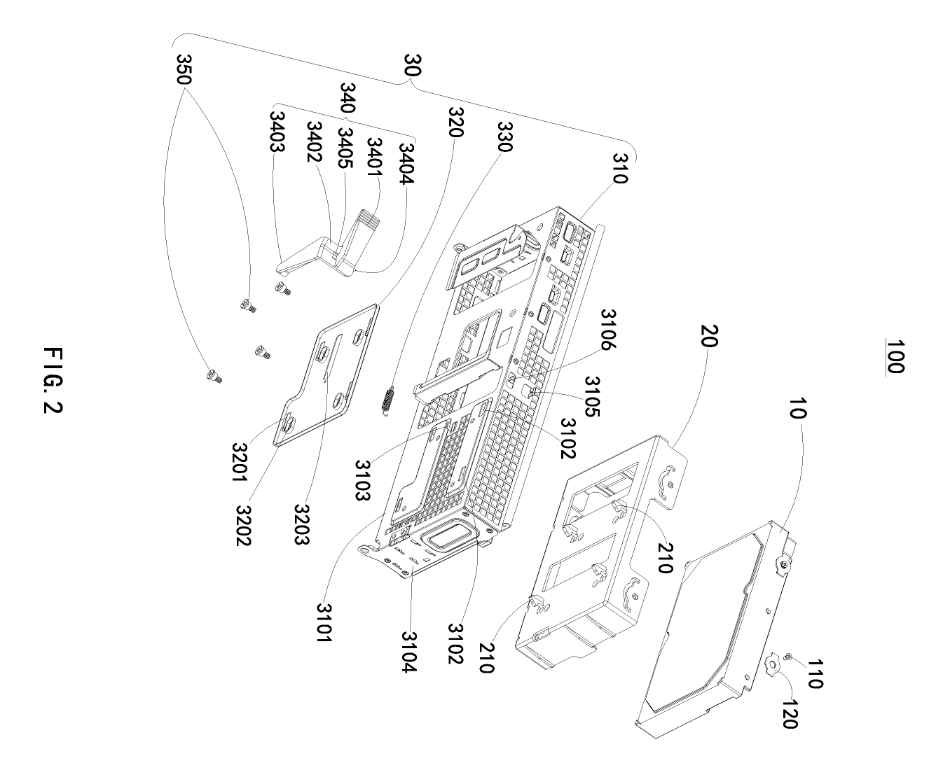

FIGS. 1-3 illustrate a storage device 100. The storage device 100 includes a hard disk drive 10 and a tool-less mounting apparatus 200 for mounting the hard disk drive 10.

The mounting apparatus 200 includes a tray 20 and a locking unit 30.

The tray 20 defines an installation space for the hard disk drive 10. The hard disk drive 10 can be accommodated in the installation space, and the hard disk drive 10 can be fixed in the tray 20 by spacers 120 and screws 110.

The tray 20 includes a hook 210.

The locking unit 30 includes a supporting bracket 310 and a sliding plate 320. The supporting bracket 310 defines a first locking slot 3102 corresponding to the hook 210.

The sliding plate 320 is slidably connected to a side of the supporting bracket 310, and the sliding plate 320 defines a second locking slot 3201 corresponding to the hook 210 and the first locking slot 3102.

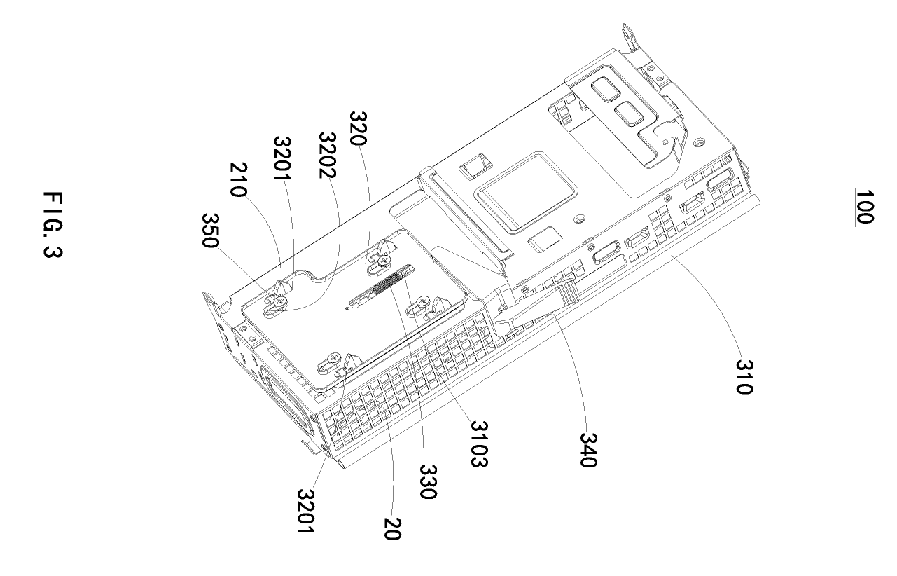

The hook 210 is coupled to the sliding plate 320 by passing through the first locking slot 3102 and the second locking slot 3201. The sliding plate 320 is slidable between an unlock position (shown in FIG. 3), where the first locking slot 3102 aligns with the second locking slot 3201 and the hook 210 is free to pass through the first locking slot 3102 and the second locking slot 3201, and a lock position (shown in FIG. 1), where the first locking slot 3102 and the second locking slot 3201 are not aligned and the hook 210 is stopped by the sliding plate 320.

The mounting apparatus 200 can further include a resilient member 330 connected between the sliding plate 320 and the supporting bracket 310.

When the sliding plate 320 is forced to slide to the unlock position, the resilient member 330 is elastically deformed, and when the sliding plate 320 is unforced, the resilient member 330 drives the sliding plate 320 to slide to the lock position and keeps the sliding plate 320 in the locking position under restoring force.

The resilient member 330 can be a hook spring. The supporting bracket 310 includes a first fixing portion 3103. The sliding plate 320 includes a second fixing portion (not shown). One end of the hook spring is fixed to the first fixing portion 3103, and the other end of the hook spring is fixed to the second fixing portion.

The sliding plate 320 can define an accommodating groove 3203, and the resilient member 330 can be accommodated in the accommodating groove 3203.

The supporting bracket 310 includes at least two guiding members 350 distributed along the sliding direction of the sliding plate 320. The sliding plate 320 defines at least two guiding slots 3202 corresponding to the at least two guiding members 350 and the guiding slots 3202 extend along the sliding direction of the sliding plate 320.

The mounting apparatus 200 can further include an unlocking member 340. The unlocking member 340 is rotatably connected to the supporting bracket 310, the unlocking member 340 includes a driving lever 3403 corresponding to the sliding plate 320.

When the unlocking member 340 is forced to rotate, the driving lever 3403 drives the sliding plate 320 to slide to the unlock position.

The unlocking member 340 can further include a pressing portion 3401, a connecting portion 3402, and a pivoting pin 3404.

The connecting portion 3402 is connected between the pressing portion 3401 and the driving lever 3403. The pivoting pin 3404 is connected to the connecting portion 3402. The supporting bracket 310 defines a pivoting hole 3105 coupled to the pivoting pin 3404.

When the pressing portion 3401 is pressed by a user, the unlocking member 340 rotates about the pivoting pin 3404, and the driving lever 3403 is rotated to drive the sliding plate 320 to slide to the unlock position.

The supporting bracket 310 includes a bottom plate 3101 and a plurality of side plates 3104 perpendicularly connected to the bottom plate 3101. The pivoting hole 3105 is defined on one of the side plates 3104 and the one of the side plates 3104 includes a supporting portion 3106 corresponding to the pivoting pin 3404.

The connecting portion 3402 defines an opening 3405 corresponding to the supporting portion 3106, and the supporting portion 3106 is pivotally received in the opening 3405 to support the pivoting pin 3404.

The embodiments shown and described above are only examples. Even though numerous characteristics and advantages of the present technology have been set forth in the foregoing description, together with details of the structure and function of the present disclosure, the disclosure is illustrative only, and changes may be made in the details, including matters of shape, size, and arrangement of the parts within the principles of the present disclosure, up to and including the full extent established by the broad general meaning of the terms used in the claims.

What is claimed is:

1. A tool-less mounting apparatus for hard disk drive comprising:
a tray defining an installation space for the hard disk drive and comprising a hook; and
a locking unit comprising:
a supporting bracket defining a first locking slot corresponding to the hook; and
a sliding plate slidably connected to a side of the supporting bracket and defining a second locking slot corresponding to the hook and the first locking slot;
wherein the hook is coupled to the sliding plate by passing through the first locking slot and the second locking slot; the sliding plate is slidable between an unlocking position, where the first locking slot aligns with the second locking slot and the hook is free to pass through the first locking slot and the second locking slot, and a locking position, where the first locking slot and the second locking slot are not aligned and the hook is stopped by the sliding plate.

2. The mounting apparatus of claim 1, wherein the mounting apparatus further comprises a resilient member connected between the sliding plate and the supporting bracket;
when the sliding plate is forced to slide to the unlocking position, the resilient member is elastically deformed; when the sliding plate is unforced, the resilient member drives the sliding plate to slide to the locking position under restoring force.

3. The mounting apparatus of claim 2, wherein the resilient member is a hook spring; the supporting bracket comprises a first fixing portion; the sliding plate comprises a second fixing portion; one end of the hook spring is fixed to the first fixing portion, and the other end of the hook spring is fixed to the second fixing portion.

4. The mounting apparatus of claim 3, wherein the sliding plate defines an accommodating groove, and the resilient member is accommodated in the accommodating groove.

5. The mounting apparatus of claim 1, wherein the supporting bracket comprises at least two guiding members distributed along the sliding direction of the sliding plate; the sliding plate defines at least two guiding slots corresponding to the at least two guiding members and the guiding slots extend along the sliding direction of the sliding plate.

6. The mounting apparatus of claim 1, wherein the mounting apparatus further comprises a unlocking member rotatably connected to the supporting bracket, the unlocking member comprises a driving lever corresponding to the sliding plate;
when the unlocking member is forced to rotate, the driving lever drives the sliding plate to slide to the unlocking position.

7. The mounting apparatus of claim 6, wherein the unlocking member further comprises:
a pressing portion;
a connecting portion; and
a pivoting pin;
wherein the connecting portion is connected between the pressing portion and the driving lever, the pivoting pin is connected to the connecting portion; the supporting bracket defines a pivoting hole coupled to the pivoting pin;
when the pressing portion is pressed, the unlocking member rotates about the pivoting pin and the driving lever is rotated to drive the sliding plate to slide to the unlocking position.

8. The mounting apparatus of claim 7, wherein the supporting bracket comprises a bottom plate and a plurality of side plates perpendicularly connected to the bottom plate; the pivoting hole is defined on one of the side plates and the one of the side plates comprises a supporting portion corresponding to the pivoting pin; the connecting portion defines an opening corresponding to the supporting portion, and the supporting portion is pivotally received in the opening to support the pivoting pin.

9. A storage device comprising:
a hard disk drive; and
a tool-less mounting apparatus to mount the hard disk drive, comprising:
a tray defining an installation space for the hard disk drive and comprising a hook; and
a locking unit comprising:
a supporting bracket defining a first locking slot corresponding to the hook; and
a sliding plate slidably connected to a side of the supporting bracket and defining a second locking slot corresponding to the hook and the first locking slot;
wherein the hook is coupled to the sliding plate by passing through the first locking slot and the second locking slot; the sliding plate is slidable between an unlocking position, where the first locking slot aligns with the second locking slot and the hook is free to pass through the first locking slot and the second locking slot, and a locking position, where the first locking slot and the second locking slot are not aligned and the hook is stopped by the sliding plate.

10. The storage device of claim 9, wherein the mounting apparatus further comprises a resilient member connected between the sliding plate and the supporting bracket;
when the sliding plate is forced to slide to the unlocking position, the resilient member is elastically deformed; when the sliding plate is unforced, the resilient member drives the sliding plate to slide to the locking position under restoring force.

11. The storage device of claim 10, wherein the resilient member is a hook spring; the supporting bracket comprises a first fixing portion; the sliding plate comprises a second fixing portion; one end of the hook spring is fixed to the first fixing portion, and the other end of the hook spring is fixed to the second fixing portion.

12. The storage device of claim 11, wherein the sliding plate defines an accommodating groove, and the resilient member is accommodated in the accommodating groove.

13. The storage device of claim 9, wherein the supporting bracket comprises at least two guiding members distributed along the sliding direction of the sliding plate; the sliding plate defines at least two guiding slots corresponding to the at least two guiding members and the guiding slots extend along the sliding direction of the sliding plate.

14. The storage device of claim 9, wherein the mounting apparatus further comprises a unlocking member rotatably connected to the supporting bracket, the unlocking member comprises a driving lever corresponding to the sliding plate;
when the unlocking member is forced to rotate, the driving lever drives the sliding plate to slide to the unlocking position.

15. The storage device of claim 14, wherein the unlocking member further comprises:
a pressing portion;
a connecting portion; and
a pivoting pin;
wherein the connecting portion is connected between the pressing portion and the driving lever, the pivoting pin is connected to the connecting portion; the supporting bracket defines a pivoting hole coupled to the pivoting pin;
when the pressing portion is pressed, the unlocking member rotates about the pivoting pin and the driving lever is rotated to drive the sliding plate to slide to the unlocking position.

16. The storage device of claim 15, wherein the supporting bracket comprises a bottom plate and a plurality of side plates perpendicularly connected to the bottom plate; the pivoting hole is defined on one of the side plates and the one of the side plates comprises a supporting portion corresponding to the pivoting pin; the connecting portion defines an opening corresponding to the supporting portion, and the supporting portion is pivotally received in the opening to support the pivoting pin.
